(19) United States
(12) Patent Application Publication
(10) Pub. No.: US 2026/0129789 A1
(43) Pub. Date: May 7, 2026

(54) ELECTRONIC CONTROL DEVICE

(71) Applicant: HYUNDAI MOBIS CO., LTD., Seoul (KR)

(72) Inventors: Hyun Seong LEE, Yongin-si (KR); Seong Hyeon PARK, Yongin-si (KR); Sung Bae JEON, Yongin-si (KR); Byeong Jun KANG, Yongin-si (KR); Hyung Soo LIM, Yongin-si (KR); Su Ji KIM, Yongin-si (KR); Byung Mo YU, Yongin-si (KR); Sun Jong OH, Yongin-si (KR)

(73) Assignee: HYUNDAI MOBIS CO., LTD., Seoul (KR)

(21) Appl. No.: 19/221,918

(22) Filed: May 29, 2025

(30) Foreign Application Priority Data
Nov. 4, 2024 (KR) 10-2024-0154344

(51) Int. Cl. H05K 7/20

(52) U.S. Cl. CPC H05K 7/20154

(57) ABSTRACT

An electronic control device includes a base part including a base plate, a panel part including a panel body disposed on a front of the base part, a panel protrusion protruding outward from the panel body, and a panel ventilation unit including openings in the panel protrusion part, and a heat dissipation part including a heat dissipation body disposed on the base part to face the base plate.

### CROSS-REFERENCE TO RELATED APPLICATION

This application claims the benefit under 35 U.S. C. § 119(a) of priority to Korean Patent Application No. 10-2024-0154344 filed on Nov. 4, 2024, in the Korean Intellectual Property Office, the entire disclosure of which is incorporated herein by reference for all purposes.

### BACKGROUND

### 1. Technical Field Exemplary embodiments of the present disclosure relate to an electronic control device, and more particularly, to an electronic control device having improved water resistance.

### 2. Related Art

As electronic control technology for automobiles develops, many mechanical components for controlling automobiles are being replaced by electronic control devices. As the components controlled by electronic control devices increase, the heat generated by electronic control devices is increasing. As a fan is applied to increase the heat dissipation of the electronic control device, the exterior and interior of the electronic control device communicate with each other, which causes a problem in that the water resistance of the electronic control device is reduced.

Accordingly, there is an increasing need for an electronic control device capable of improving water resistance while increasing the amount of heat dissipation of the electronic control device.

The background technology of the present disclosure is disclosed in Korean Patent Registration No. 10-1610892 (registered on Apr. 4, 2016, entitled “ELECTRONIC CONTROL DEVICE OF VEHICLE USING POTTING LAYER AND MANUFACTURING METHOD THEREOF”).

### SUMMARY

Various embodiments of the present disclosure are directed to an electronic control device having improved water resistance.

An electronic control device according to the present disclosure includes a base part including a base plate, a panel part including a panel body disposed on a front of the base part, a panel protrusion protruding outward from the panel body, and a panel ventilation unit including openings in the panel protrusion part, and a heat dissipation part including a heat dissipation body disposed on the base part to face the base plate.

The electronic control device may further include a heat dissipation fan disposed on an inside of the panel body to move air from outside of the panel part to inside of the panel part through the panel ventilation part.

The panel ventilation unit may include panel lower openings that open toward a lower side of the panel body.

The panel part may include panel lower ribs disposed to connect the panel body and the panel protrusion and crossing the panel lower openings.

The panel ventilation unit may include panel side openings that open a side of the panel protrusion.

The panel ventilation unit may include panel front openings disposed in a direction in which the panel protrusion protrudes.

The panel ventilation unit may include panel front ribs that surround the panel front openings and protrude in a direction in which the panel protrusion protrudes.

The base part may include a side plate including a first side plate and a second side plate that extend from the base plate and are disposed on respective sides of the base plate, a rear plate that extends from the base plate and is disposed to face the panel body, and a front plate that extends from the base plate and is disposed between the rear plate and the panel body.

The electronic control device may further include a control part that is disposed between the base part and the heat dissipation part to generate heat.

The heat dissipation part may include a heat dissipation body disposed to face the base plate, and a heat dissipation fin unit that is disposed on an outside of the heat dissipation body to dissipate heat, and the electronic control device may further include a cover part disposed to cover the heat dissipation fin unit.

A width of the panel protrusion may be set to 40 mm to 80 mm, a protrusion length of the panel protrusion protruding from the panel body may be set to 20 mm to 40 mm, the height of the panel body is set to 40 mm to 100 mm, and the width of the panel body may be set to 120 mm to 250 mm.

The panel protrusion may be disposed between one end and the other end of the panel body.

The panel protrusion may include: a panel protrusion body protruding from the panel body to the outside of the panel body; a panel inflow slope disposed on the lower side of the panel protrusion body and connected to the panel ventilation unit, and extending toward the panel body; a panel inflow connection extending from the panel inflow slope; and a panel inflow guide extending from the panel inflow connection and connected to the panel body.

The panel part may be disposed to connect the panel body and the panel protrusion, and may include a panel side rib crossing the panel side opening. The panel front opening may be provided in multiple numbers, and a diameter of the panel front opening may be provided to be 0.5 mm to 2.0 mm.

The electronic control device according to the present disclosure can improve water resistance performance. In addition, the electronic control device according to the present disclosure can improve heat dissipation performance.

### BRIEF DESCRIPTION OF THE DRAWINGS

FIG. 1 is a perspective view of an electronic control device according to an embodiment of the present disclosure from a first perspective.

FIG. 2 is an exploded perspective view of an electronic control device according to an embodiment of the present disclosure from a first perspective.

FIG. 3 is a perspective view of an electronic control device according to an embodiment of the present disclosure from a second perspective.

FIG. 4 is an exploded perspective view of an electronic control device according to an embodiment of the present disclosure from a second perspective.

FIG. 5 is a perspective view of a panel part according to a first embodiment of the present disclosure.

FIG. 6 is a perspective view of a panel part according to a second embodiment of the present disclosure.

FIG. 7 is a perspective view of a panel part according to a third embodiment of the present disclosure.

FIG. 8 illustrates a cross-section of a panel part according to a third embodiment of the present disclosure.

FIG. 9 is an enlarged view of a cross-section of a panel part according to a third embodiment of the present disclosure.

### DETAILED DESCRIPTION

Hereinafter, an electronic control device according to the present disclosure is described in detail below with reference to the accompanying drawings through various exemplary embodiments. It should be considered that the thickness of each line or the size of each component in the drawings may be exaggeratedly illustrated for clarity and convenience of description.

In addition, terms to be described below have been defined by taking into consideration their functions in the present disclosure, and may be different depending on a user or operator's intention or practice. Accordingly, such terms should be interpreted based on the overall contents of this specification.

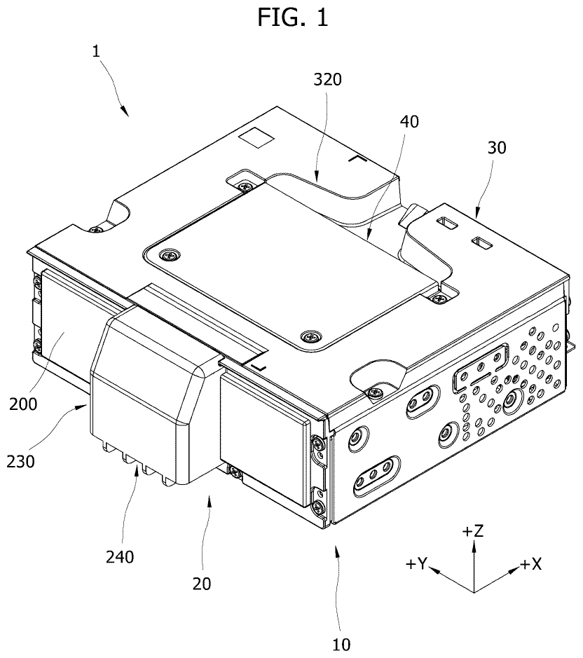

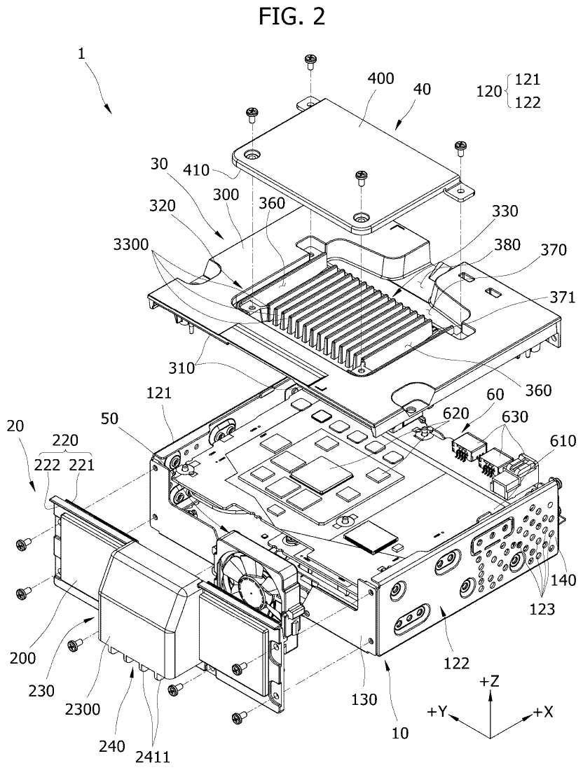

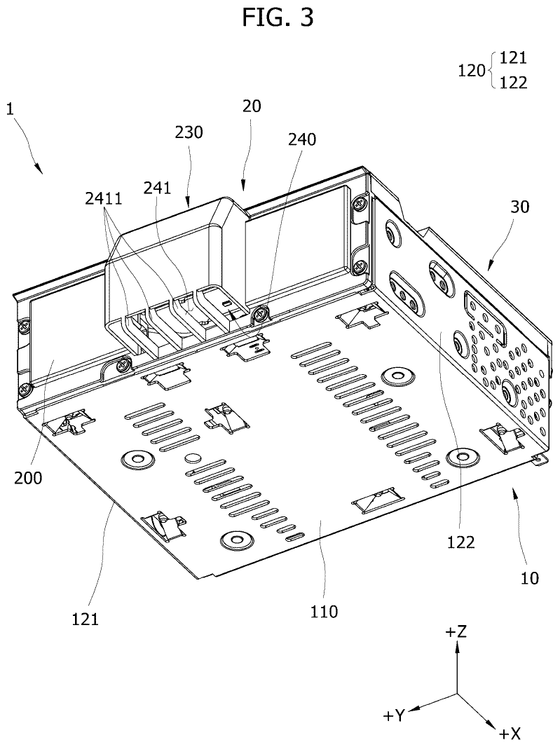

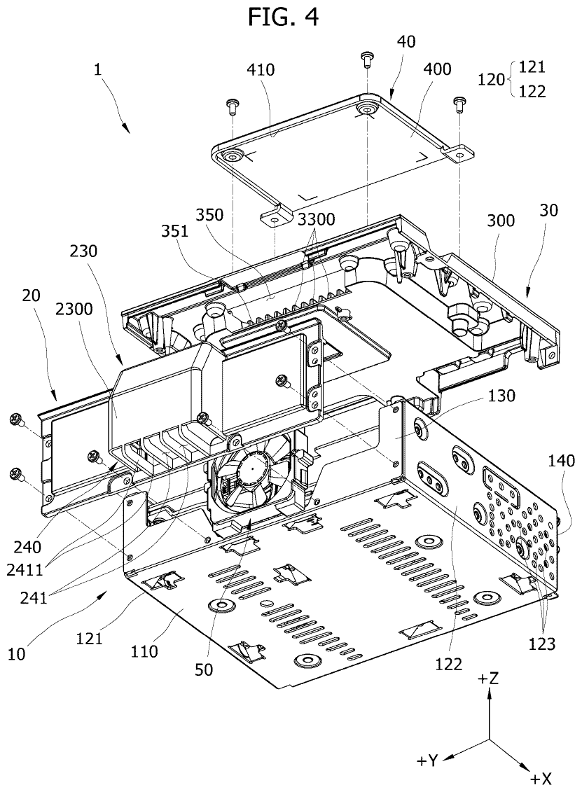

FIG. 1 is a perspective view of an electronic control device according to an embodiment of the present disclosure from a first perspective. FIG. 2 is an exploded perspective view of an electronic control device according to an embodiment of the present disclosure from a first perspective. FIG. 3 is a perspective view of an electronic control device according to an embodiment of the present disclosure from a second perspective. FIG. 4 is an exploded perspective view of an electronic control device according to an embodiment of the present disclosure from a second perspective.

Referring to FIG. 1 to FIG. 4, the electronic control device 1 includes a base part 10, a panel part 20, a heat dissipation part 30, a cover part 40, a heat dissipation fan 50, and a control part 60. The base part 10, the panel part 20, the heat dissipation part 30, and/or the cover part 40 form the exterior of the electronic control device 1.

The base part 10 constitutes a lower surface (e.g., in the −Z-axis direction), a side surface (e.g., in the Y-axis direction), a portion of a front surface (e.g., in the −X-axis direction), and a portion of a rear surface (e.g., in the +X-axis direction) of the electronic control device 1.

The panel part 20 includes holes so that an outer side (e.g., in the −X-axis direction) and an inner side (e.g., in the +X-axis direction) of the panel part 20 communicate with each other. The holes are arranged at various locations at the panel part 20. Accordingly, air outside the panel part 20 passes through the panel part 20 and moves inside the panel part 20. The panel part 20 is disposed on the front side (e.g., in the −X-axis direction) of the base part 10. The panel part 20 is coupled to the base part 10 and is coupled to the heat dissipation part 30.

The heat dissipation part 30 dissipates heat generated from the electronic control device 1. The heat dissipation part 30 is disposed on an upper side (e.g., in the +Z-axis direction) of the base part 10. The heat dissipation part 30 is coupled to the base part 10 and the panel part 20. Foreign substances, for example, water existing between the heat dissipation part 30 and the panel part 20 are discharged to the outside of the electronic control device 1 through the panel part 20.

The exterior of the electronic control device 1 is provided in a box shape by the base part 10, the panel part 20, and the heat dissipation part 30.

The cover part 40 is disposed at the heat dissipation part 30 and prevents the foreign substances from entering the electronic control device 1. The cover part 40 comes into contact with the heat dissipation part 30 and performs a heat dissipation function.

The heat dissipation fan 50 is disposed at the panel part 20 and allows air to flow. According to an embodiment, the heat dissipation fan 50 is disposed inside the panel part 20 (e.g., in the +X-axis direction) to allow air outside of the electronic control device 1 to flow into the electronic control device 1. The air flowing by the heat dissipation fan 50 dissipates the heat generated in the electronic control device 1.

The control part 60 electronically controls the configuration of a vehicle. The control part 60 is disposed in a space surrounded by the base part 10, the panel part 20, and the heat dissipation part 30. The control part 60 includes a circuit board 610, electronic components 620, and plug units 630.

The circuit board 610 is disposed in the electronic control device 1, the electronic components 620 are disposed on the circuit board 610 and electrically and/or electronically connected to the circuit board 610, and the plug units 630 are electrically and/or electronically connected to the circuit board 610 and/or the electronic components 620. According to an embodiment, the plug units 630 are disposed on the rear side (e.g., in the +X-axis direction) of the base part 10.

When the control part 60 operates, heat may be generated in the control part 60. The heat generated in the control part 60 may be discharged to the outside of the electronic control device 1 through the heat dissipation part 30.

Hereinafter, with reference to FIG. 1 to FIG. 4, the detailed configuration of the electronic control device 1 is described.

The base part 10 includes a base plate 110, side plates 120, a front plate 130, and a rear plate 140.

The base plate 110 is disposed parallel to a plane (e.g., X-Y plane). The base plate 110 constitutes a lower surface (e.g., in the −Z axis direction) of the electronic control device 1. The base plate 110 may be provided in an approximately square shape. The shape of the base plate 110 is not limited to the square shape, and the base plate 110 may be provided in various shapes.

The side plates 120 are disposed on the sides (e.g., in the Y-axis direction) of the base plate 110. The side plates 120 includes a first side plate 121 and a second side plate 122. The first side plate 121 is disposed on one side (e.g., in the +Y-axis direction) of the base plate 110, and the second side plate 122 is disposed on the other side (e.g., in the −Y-axis direction) of the base plate 110.

According to an embodiment, the first side plate 121 and/or the second side plate 122 are/is disposed integrally with the base plate 110. The first side plate 121 and the second side plate 122 extend from the base plate 110 and are bent upward (e.g., in the +Z-axis direction). An angle formed by the first side plate 121 and/or the second side plate 122 and the base plate 110 is approximately 70 degrees to 110 degrees. More specifically, the angle formed by the first side plate 121 and/or the second side plate 122 and the base plate 110 is approximately 90 degrees.

As the first side plate 121 and/or the second side plate 122 are/is disposed integrally with the base plate 110, foreign substances are prevented from entering the electronic control device 1.

The base part 10 further includes base holes 123 that penetrate the side plates 120. The base holes 123 are disposed at the first side plate 121 and/or the second side plate 122. Because the base holes 123 are disposed at the base part 10, the inside and outside of the electronic control device 1 communicate with each other.

The front plate 130 is disposed on the front side (e.g., in the −X-axis direction) of the base plate 110.

According to an embodiment, the front plate 130 is disposed integrally with the base plate 110. The front plate 130 extends from the base plate 110 and is bent upward (e.g., in the +Z-axis direction). An angle formed by the front plate 130 and the base plate 110 is approximately 70 degrees to 110 degrees. More specifically, the angle formed by the front plate 130 and the base plate 110 is approximately 90 degrees.

The front plate 130 is in contact with the side plates 120. According to an embodiment, the front plate 130 is coupled to the side plates 120. More specifically, the front plate 130 is bolted to the first side plate 121 and/or the second side plate 122.

A waterproofing member (not shown) may be disposed between the front plate 130 and the side plates 120. Accordingly, the water resistance of the electronic control device 1 can be improved.

The rear plate 140 is disposed on the rear side (e.g., in the +X-axis direction) of the base plate 110.

According to an embodiment, the rear plate 140 is disposed integrally with the base plate 110. The rear plate 140 extends from the base plate 110 and is bent upward (e.g., in the +Z-axis direction). An angle formed by the rear plate 140 and the base plate 110 is approximately 70 degrees to 110 degrees. More specifically, the angle formed by the rear plate 140 and the base plate 110 is approximately 90 degrees.

The rear plate 140 is in contact with the side plates 120. According to an embodiment, the rear plate 140 is coupled to the side plates 120. More specifically, the rear plate 140 is bolted to the first side plate 121 and/or the second side plate 122.

A waterproofing member (not shown) may be disposed between the rear plate 140 and the side plates 120. Accordingly, the water resistance of the electronic control device 1 can be improved.

The panel part 20 is disposed in front (e.g., in the −X-axis direction) of the base plate 110. According to an embodiment, the panel part 20 is coupled to the base plate 110 and/or the front plate 130.

The panel part 20 includes a panel body 200, a panel protrusion 230, and a panel ventilation unit 240.

The panel body 200 is provided in an approximately square shape. The shape of the panel body 200 is not limited to the square shape, and the panel body 200 may be provided in various shapes.

The heat dissipation part 30 is inserted into the panel body 200. According to an embodiment, a heat dissipation body 300 of the heat dissipation part 30 is inserted into a groove (not shown) formed on the upper side (e.g., in the +Z-axis direction) of the panel body 200. More specifically, heat dissipation coupling protrusions 310 of the heat dissipation body 300 are inserted into the groove formed in the panel body 200.

As the heat dissipation coupling protrusions 310 of the heat dissipation body 300 are inserted into the groove formed in the panel body 200, foreign substances existing between the panel body 200 and the heat dissipation body 300 may not enter the electronic control device 1.

Panel body coupling units 220 are disposed at the panel body 200. According to an embodiment, the panel body coupling units 220 are disposed on the upper side (e.g., in the +Z-axis direction) of the panel body 200. The panel body coupling units 220 are coupled to the heat dissipation body 300 of the heat dissipation part 30. According to an embodiment, the heat dissipation coupling protrusions 310 of the heat dissipation body 300 are inserted into the panel body coupling units 220.

Each of the panel body coupling units 220 includes a panel body inner coupling portion 221 and a panel body outer coupling portion 222.

The panel body inner coupling portion 221 and/or the panel body outer coupling portion 222 extend along one axis (e.g., Y-axis). The panel body inner coupling portion 221 is disposed closer to the rear plate 140 than the panel body outer coupling portion 222. According to an embodiment, the panel body inner coupling portion 221 is disposed in the +X-axis direction than the panel body outer coupling portion 222.

Grooves are disposed at the panel body 200 between the panel body inner coupling portions 221 and the panel body outer coupling portions 222. As the heat dissipation coupling protrusions 310 of the heat dissipation body 300 are inserted into the grooves formed at the panel body 200 disposed between the panel body inner coupling portions 221 and the panel body outer coupling portions 222, foreign substances existing in the heat dissipation part 30 move between the panel part 20 and the heat dissipation part 30 and are not introduced into the electronic control device 1.

In this manner, as the grooves are disposed in the panel body 200 between the panel body inner coupling portions 221 and the panel body outer coupling portions 222 and the heat dissipation coupling protrusions 310 are inserted into the grooves disposed in the panel body 200, the foreign substances existing in the heat dissipation part 30 may not enter the electronic control device 1.

A panel protrusion 230 is disposed on the panel body 200. The panel protrusion 230 is disposed to protrude from the panel body 200. According to an embodiment, the panel protrusion 230 protrudes toward one side (e.g., in the −X-axis direction) of the panel body 200.

The panel protrusion 230 includes a panel protrusion body 2300. A shape of the panel protrusion body 2300 may vary. According to an embodiment, a panel ventilation unit 240 is disposed on the lower side (e.g., in the −Z-axis direction) of the panel protrusion body 2300.

A cross-sectional shape of the panel protrusion body 2300 may be inclined toward one side (e.g., +X-axis direction) from the lower side (e.g., −Z-axis direction) to the upper side (e.g., +Z-axis direction).

The panel protrusion body 2300 is provided in an approximately square shape. The shape of the panel protrusion body 2300 is not limited thereto, and the panel protrusion body 2300 may be provided in various shapes.

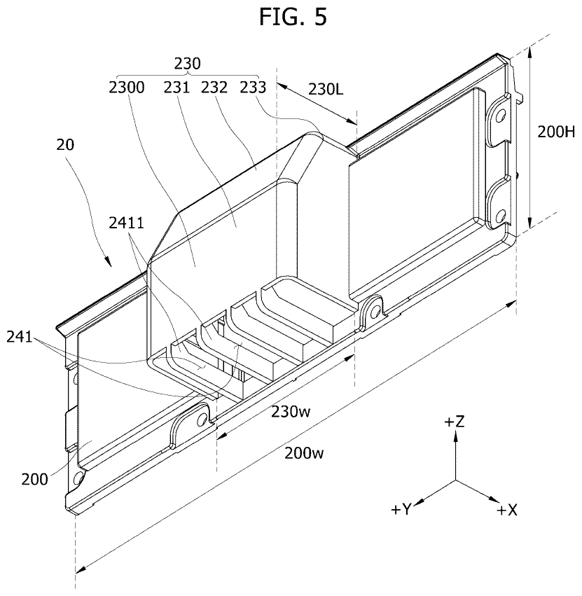

The panel protrusion 230 is described later in more detail together with FIG. 5 to FIG. 7.

The panel ventilation unit 240 is disposed in the panel protrusion 230. The panel ventilation unit 240 may be provided as openings in the panel protrusion 230. Air outside the electronic control device 1 may be introduced into the electronic control device 1 through the panel ventilation unit 240.

The panel ventilation unit 240 is disposed on the lower side (e.g., in the −Z-axis direction), on the side (e.g., in the Y-axis direction), or on the front side (e.g., in the −X-axis direction) of the panel protrusion 230.

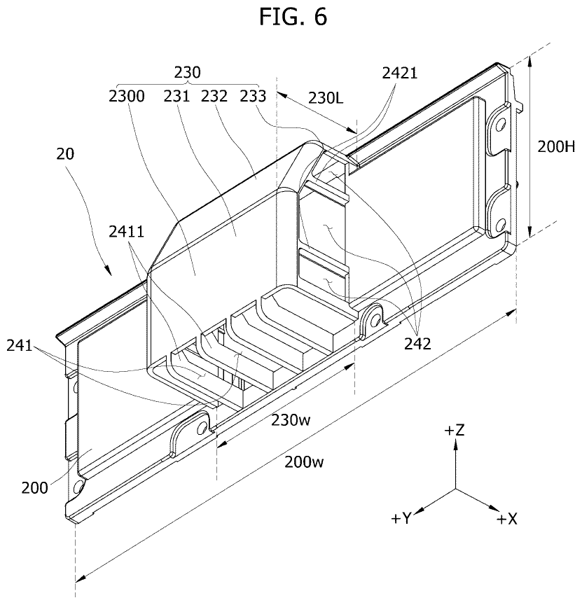

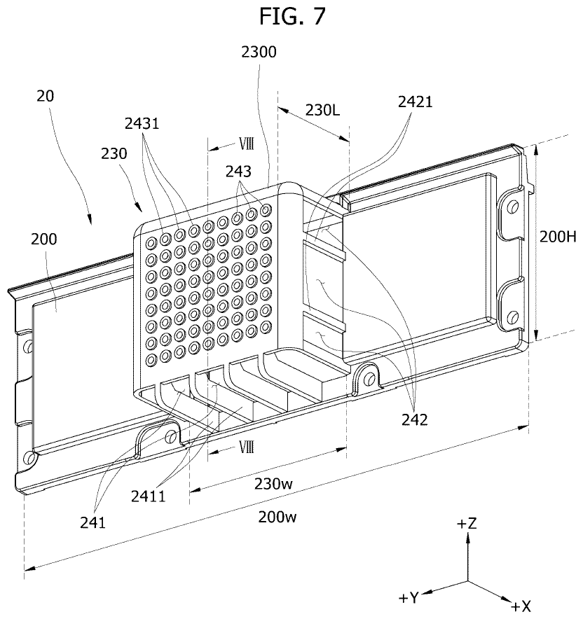

Embodiments in which the panel ventilation unit 240 is disposed on the lower side (e.g., in the −Z-axis direction) of the panel protrusion 230 are illustrated in FIG. 1 to FIG. 8, embodiments in which the panel ventilation unit 240 is disposed on the side (e.g., in the Y-axis direction) of the panel protrusion 230 are illustrated in FIG. 6 to FIG. 8, and embodiments in which the panel ventilation unit 240 is disposed on the front side (e.g., in the −X-axis direction) of the panel protrusion 230 are illustrated in FIG. 7 to FIG. 9.

The panel ventilation unit 240 is described later in more detail together with FIG. 5 to FIG. 9.

The heat dissipation part 30 is disposed on the upper side (e.g., in the +Z-axis direction) of the base part 10. The heat dissipation part 30 is coupled to the base part 10 and the panel part 20.

The heat dissipation part 30 includes the heat dissipation body 300, the heat dissipation coupling protrusions 310, a heat dissipation body concave unit 320, a heat dissipation fin unit 330, a heat dissipation body heat dissipation hole (e.g., the heat dissipation body heat dissipation hole 350 of FIG. 4), a heat dissipation receiving unit 360, a heat dissipation path 370, and a heat dissipation drain unit 380.

The heat dissipation body 300 is disposed to face the base plate 110. A shape of the heat dissipation body 300 may be approximately square. The shape of the heat dissipation body 300 is not limited to square, and the heat dissipation body 300 may be provided in various shapes.

The heat dissipation coupling protrusions 310 are disposed to protrude from the heat dissipation body 300. The heat dissipation coupling protrusions 310 are positioned under the heat dissipation body 300 (e.g., in the −Z-axis direction) and protrude from the heat dissipation body 300. The heat dissipation coupling protrusions 310 extend along one direction (e.g., in the Y-axis direction).

The heat dissipation coupling protrusions 310 are inserted into the panel part 20. According to an embodiment, the heat dissipation coupling protrusions 310 are inserted into the groove formed in the panel body 200. The groove formed in the panel body 200 is disposed between the panel body inner coupling portion 221 and the panel body outer coupling portion 222.

In this way, the heat dissipation coupling protrusions 310 are disposed in the grooves formed in the panel body 200 between the panel body inner coupling portions 221 and the panel body outer coupling portions 222, so that foreign substances existing between the heat dissipation body 300 and the panel body 200 may not enter the electronic control device 1.

The heat dissipation body concave unit 320 is provided as a concave space in the heat dissipation body 300. According to an embodiment, the heat dissipation body concave unit 320 is provided as a concave recess facing downward (e.g., in the −Z-axis direction) on an upper surface (e.g., in the +Z-axis direction) of the heat dissipation body 300.

The heat dissipation fin unit 330, the heat dissipation body heat dissipation hole 350, the heat dissipation receiving unit 360, the heat dissipation path 370, and the heat dissipation drain unit 380 are disposed in the heat dissipation body concave unit 320.

The heat dissipation fin unit 330 is disposed in the heat dissipation body concave unit 320. The heat dissipation fin unit 330 dissipates heat generated in the electronic control device 1 to the outside of the electronic control device 1. The heat dissipation fin unit 330 includes heat dissipation fins 3300.

A plurality of heat dissipation fins 3300 are provided. The heat dissipation fins 3300 are provided to protrude from the heat dissipation body 300. According to an embodiment, the heat dissipation fins 3300 are disposed to extend along one direction (e.g., X-axis direction). The plurality of heat dissipation fins 3300 are disposed along another direction (e.g., Y-axis direction).

In this way, as the heat dissipation fins 3300 extend along one direction (e.g., X-axis direction) and are disposed along another direction (e.g., Y-axis direction), air introduced into the electronic control device 1 from the panel ventilation unit 240 can flow along one direction (e.g., X-axis direction) and move between the plurality of heat dissipation fins 3300. Furthermore, it is possible to reduce the resistance of air flow that may occur between the plurality of heat dissipation fins 3300 and increase the flow rate of air in contact with the heat dissipation fins 3300.

The heat dissipation body heat dissipation hole 350 configured as a hole penetrating the heat dissipation body 300 is disposed on one side of the heat dissipation fin unit 330. According to an embodiment, the heat dissipation body heat dissipation hole 350 is disposed between the front plate 130 and the heat dissipation fin unit 330. More specifically, the heat dissipation body heat dissipation hole 350 is disposed in the −X-axis direction of the heat dissipation fin unit 330.

As the heat dissipation body heat dissipation hole 350 is disposed in the heat dissipation body 300, the flowing air passes through the heat dissipation body heat dissipation hole 350 and moves to the heat dissipation fin unit 330 by the heat dissipation fan 50 disposed in the panel ventilation unit 240. Accordingly, a flow rate of the air in contact with the heat dissipation fin unit 330 increases, so that the heat dissipation performance of the electronic control device 1 can be improved.

A heat dissipation body guide 351 is disposed to be inclined in the heat dissipation body heat dissipation hole 350. The heat dissipation body guide 351 is disposed to be inclined in the −Z-axis direction as goes toward the −X-axis. As the heat dissipation body guide 351 is disposed to be inclined in this way, the flow rate of air flowing from the panel ventilation unit 240 to the heat dissipation fin unit 330 can increase. Accordingly, the heat dissipation performance of the electronic control device 1 can be improved.

The heat dissipation receiving unit 360 is disposed adjacent to the heat dissipation fin unit 330. The heat dissipation receiving unit 360 is provided as a space capable of receiving foreign substances flowing in from the outside of the electronic control device 1. According to an embodiment, the heat dissipation receiving unit 360 is disposed on both sides (e.g., in the Y-axis direction) of the heat dissipation fin unit 330.

Because the heat dissipation receiving unit 360 is disposed on both sides of the heat dissipation fin unit 330, the probability of foreign substances flowing into the electronic control device 1 can be reduced.

The heat dissipation path 370 is disposed in the heat dissipation body concave unit 320. The heat dissipation path 370 is provided as a path through which air or foreign substances move. The heat dissipation path 370 is connected between the heat dissipation fins 3300, the heat dissipation receiving unit 360, and the heat dissipation drain unit 380.

The heat dissipation path 370 is formed to be inclined so that movement of foreign substances existing in the heat dissipation path 370 can be induced. According to an embodiment, the foreign substances existing in the heat dissipation path 370 move to the heat dissipation drain unit 380. The heat dissipation path 370 is disposed to be inclined in the −Z-axis direction as it goes in the +X-axis direction.

A heat dissipation path step 371 is disposed between the heat dissipation path 370 and the plurality of heat dissipation fins 3300. The heat dissipation path step 371 forms a step between the heat dissipation path 370 and the heat dissipation fins 3300. Accordingly, foreign substances existing in the heat dissipation path 370 can be prevented from moving to the heat dissipation fin 3300 by the heat dissipation path step 371.

The heat dissipation drain part 380 is disposed on one side (e.g., in the +X-axis direction) of the heat dissipation path 370. The heat dissipation drain part 380 is connected to the heat dissipation path 370. As the heat dissipation drain unit 380 is connected to the heat dissipation path 370, the foreign substances existing in the heat dissipation path 370 can be discharged to the outside of the electronic control device 1 through the heat dissipation drain unit 380.

The heat dissipation drain unit 380 is disposed to be inclined. According to an embodiment, the heat dissipation drain unit 380 is disposed to be inclined in the −Z-axis direction as it goes in the +X-axis direction. Accordingly, the foreign substances can be smoothly discharged through the heat dissipation drain unit 380.

The cover part 40 is disposed on the upper side (e.g., in the +Z-axis direction) of the heat dissipation body concave unit 320. According to an embodiment, the cover part 40 is disposed to cover the heat dissipation body concave unit 320. Because the cover part 40 is disposed on the upper side of the heat dissipation body concave unit 320, foreign substances can be prevented from directly flowing into the heat dissipation fin unit 330. In addition, because the cover part 40 is disposed on the upper side of the heat dissipation body concave unit 320, foreign substances can be prevented from moving directly to the heat dissipation body heat dissipation hole 350 formed in the heat dissipation body 300.

The cover part 40 includes a cover body 400 and a cover body protrusion 410. The cover body 400 is disposed to cover the heat dissipation body concave unit 320 to prevent foreign substances from moving to the heat dissipation fin unit 330 and the heat dissipation body heat dissipation hole 350.

The cover body protrusion 410 is disposed to protrude from the cover body 400. According to an embodiment, the cover body protrusion 410 is configured to be bent from one end (e.g., in the −X-axis direction) of the cover body 400 toward the lower side (e.g., in the −Z-axis direction) so as to protrude from the cover body 400.

The cover body protrusion 410 comes into contact with the heat dissipation body 300. A protrusion length of the cover body protrusion 410 may be longer than the thickness of the cover body 400. As the cover body protrusion 410 formed to be longer than the thickness of the cover body 400 comes into contact with the heat dissipation body 300, a contact area between the heat dissipation body 300 and the cover body 400 can be increased. Accordingly, the probability of foreign substances flowing into the electronic control device 1 can be reduced.

In this way, as the cover part 40 is disposed on the upper side of the heat dissipation body concave unit 320, the probability of foreign substances flowing into the electronic control device 1 can be reduced.

The heat dissipation fan 50 is disposed adjacent to the panel protrusion 230 to allow air outside the electronic control device 1 to flow into the electronic control device 1. Accordingly, the flow rate of air flowing into the electronic control device 1 increases, thereby improving the heat dissipation performance of the electronic control device 1.

The heat dissipation fan 50 moves the air outside the panel ventilation unit 240 through the panel ventilation unit 240 into the electronic control device 1. Accordingly, the flow rate of air flowing into the electronic control device 1 increases, thereby improving the heat dissipation performance of the electronic control device 1.

The horizontal (e.g., Y-axis direction) and vertical (e.g., Z-axis direction) sizes of the heat dissipation fan 50 are set to be approximately 30 mm to 70 mm. According to an embodiment, the horizontal and vertical sizes of the heat dissipation fan 50 are set to be approximately 40 mm to 60 mm.

FIG. 5 is a perspective view of a panel part according to a first embodiment of the present disclosure. FIG. 6 is a perspective view of a panel part according to a second embodiment of the present disclosure. FIG. 7 is a perspective view of a panel part according to a third embodiment of the present disclosure.

Referring to FIG. 5 to FIG. 7, the panel part 20 is confirmed. A panel body 200 of the panel part 20 is provided in an approximately square shape. The shape of the panel body 200 is not limited to a square, and the panel body 200 may be provided in various shapes.

A width (e.g., in the Y-axis direction) of the panel body 200 may be defined as a panel body width 200W. The panel body width 200W may be set to approximately 100 mm to 300 mm. According to an embodiment, the panel body width 200W is set to be approximately 120 mm to 250 mm. More specifically, the panel body width 200W is set to be approximately 150 mm to 220 mm.

A height (e.g., in the Z-axis direction) of the panel body 200 may be defined as a panel body height 200H. The panel body height 200H may be set to be approximately 40 mm to 150 mm. According to an embodiment, the panel body height 200H is set to be approximately 50 mm to 120 mm. More specifically, the panel body height 200H is set to be approximately 60 mm to 100 mm.

The panel protrusion 230 is disposed to protrude from the panel body 200.

A width (e.g., in the Y-axis direction) of the panel protrusion 230 may be defined as the panel protrusion width 230W. The panel protrusion width 230W may be set to be 20 mm to 100 mm. According to an embodiment, the panel protrusion width 230W is set to 40 mm to be 80 mm. More specifically, the panel protrusion width 230W is set to be 50 mm to 70 mm.

A length of the panel protrusion 230 protruding from the panel body 200 may be defined as protrusion length 230L of the panel protrusion. The protrusion length 230L of the panel protrusion may be set to be approximately 10 mm to 50 mm. According to an embodiment, the panel protrusion length 230L is set to be approximately 20 mm to 40 mm. More specifically, the panel protrusion length 230L is set to be approximately 25 mm to 35 mm.

The panel protrusion 230 is disposed between one end (e.g., in the +Y-axis direction) and the other end (e.g., in the −Y-axis direction) of the panel body 200. According to an embodiment, the panel protrusion 230 is disposed at the center of the panel body 200. The position of the panel protrusion 230 disposed on the panel body 200 is not limited to the center of the panel body 200. Accordingly, the panel protrusion 230 may be disposed closer to one end (e.g., in the −Y-axis direction) of the panel body 200 than to the other end (e.g., in the +Y-axis direction), or may be disposed closer to one end (e.g., in the +Y-axis direction) of the panel body 20) than to the other end (e.g., in the −Y-axis direction).

Referring to FIG. 5 and FIG. 6, the panel protrusion 230 includes a panel protrusion body 2300, a panel inflow slope 231, a panel inflow connection 232, and a panel inflow guide 233.

The panel protrusion body 2300 is connected to the panel body 200 and protrudes in one direction (e.g., in the −X-axis direction).

The panel inflow guide 233 is connected to the panel body 200 and protrudes in one direction (e.g., in the −X-axis direction). The panel inflow guide 233 extends parallel to the −X-axis direction from the panel body 200. Alternatively, the panel inflow guide 233 extends in an arbitrary direction between the −X axis and the −Z axis from the panel body 200. According to an embodiment, the direction in which the panel inflow guide 233 extends and the surface of the panel body 200 may form an angle of 90 degrees or less.

The panel inflow connection 232 is connected to the panel inflow guide 233 and extends in one direction (e.g., in the −Z-axis direction). Alternatively, the panel inflow connection 232 is connected to the panel inflow guide 233 and extends in an arbitrary direction between the −X-axis and the −Z-axis. According to an embodiment, the angle formed by the direction in which the panel inflow connection 232 extends and the direction in which the panel inflow guide 233 extends may be set to be 180 degrees or less.

The panel inflow slope 231 is connected to the panel inflow connection 232 and extends in one direction (e.g., in the −Z axis direction). Alternatively, the panel inflow slope 231 is connected to the panel inflow connection 232 and extends in an arbitrary direction between the −X axis and the −Z axis. According to an embodiment, the direction in which the panel inflow slope 231 extends may be set closer to the −X-axis direction than the direction in which the panel inflow connection 232 extends. According to another embodiment, the direction in which the panel inflow slope 231 extends may be set closer to the −Z-axis direction than the direction in which the panel inflow connection 232 extends.

In this way, because the panel protrusion 230 is disposed in various shapes and air outside the electronic control device 1 flows into the electronic control device 1 through the panel protrusion 230, air resistance due to the panel protrusion 230 can be reduced.

Referring to FIGS. 5 and 7, the panel ventilation unit 240 includes panel lower openings 241. The panel lower openings 241 are positioned at the lower portion (e.g., in the −Z axis direction) of the panel protrusion 230. The panel lower openings 241 are provided as openings through which the air outside the electronic control device 1 flows and function as openings.

The panel ventilation unit 240 includes panel lower ribs 2411 crossing the panel lower openings 241. The panel lower ribs 2411 are disposed to connect the panel protrusion 230 and the panel body 200. A plurality of panel lower ribs 2411 may be provided. The panel lower ribs 2411 are disposed to connect the panel protrusion 230 and the panel body 200, thereby preventing foreign substances from entering the electronic control device 1 and supporting the panel protrusion 230, and minimizing deformation of the panel protrusion 230 due to external force.

Referring to FIG. 6 and FIG. 7, the panel ventilation unit 240 includes panel side openings 242. The panel side openings 242 are disposed on the side (e.g., in the Y-axis direction) of the panel protrusion 230. The panel side openings 242 are provided as openings through which the air outside the electronic control device 1 flows and function as openings.

The panel ventilation unit 240 includes panel side ribs 2421 crossing the panel side openings 242. The panel side ribs 2421 are disposed to connect the panel protrusion 230 and the panel body 200. A plurality of panel side ribs 2421 may be provided. The panel side ribs 2421 are disposed to connect the panel protrusion 230 and the panel body 200, thereby preventing foreign substances from entering the electronic control device 1 and supporting the panel protrusion 230, and minimizing deformation of the panel protrusion 230 due to external force.

As shown in FIG. 6 and FIG. 7, the panel ventilation unit 240 includes the panel lower openings 241 and/or the panel side openings 242. Accordingly, only the panel lower openings 241, only the panel side openings 242, or both the panel lower openings 241 and the panel side openings 242 may be disposed in the panel protrusion 230.

The panel ventilation unit 240 includes the panel lower ribs 2411 and/or the panel side ribs 2421. Accordingly, only the panel lower ribs 2411, only the panel side ribs 2421, or both the panel lower ribs 2411 and the panel side ribs 2421 may be disposed on the panel protrusion 230.

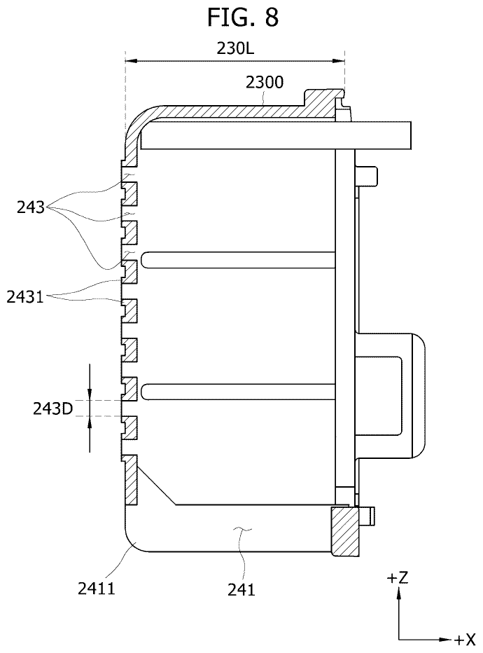

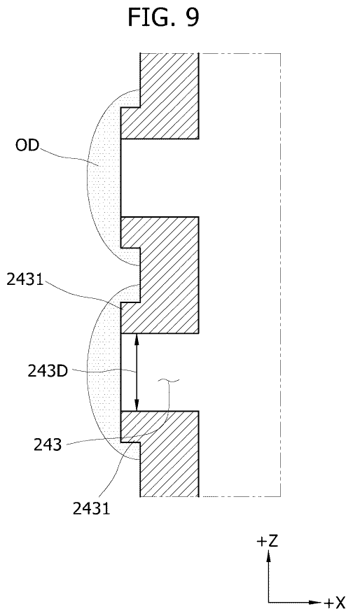

FIG. 7 is a perspective view of a panel part of a third embodiment of the present disclosure. FIG. 8 illustrates a cross-section of the panel part according to the third embodiment of the present disclosure. FIG. 9 is an enlarged view of a cross-section of the panel part according to the third embodiment of the present disclosure.

Referring to FIG. 7 to FIG. 9, the third embodiment of the panel part 20 is described.

A panel protrusion 230 is disposed on a panel body 200. The panel protrusion 230 includes a panel protrusion body 2300, and the panel protrusion body 2300 is provided in an approximately square shape. The shape of the panel protrusion body 2300 is provided in an approximately hexahedron.

Panel front openings 243 are provided as holes on one side (e.g., in the −X-axis direction) of the panel protrusion body 2300. A plurality of panel front openings 243 may be provided.

Panel front ribs 2431 are disposed to surround the panel front openings 243 in the panel protrusion body 2300. The panel front ribs 2431 protrude to one side (e.g., in the −X-axis direction) while surrounding the panel front openings 243.

A shape of the panel front opening 243 may be various, such as a circle, a square, a closed curve, etc. According to an embodiment, the shape of the panel front opening 243 is a circle. A diameter of the panel front opening 243 is defined as a panel front opening diameter 243D.

Because the panel front openings 243 are disposed in the panel protrusion body 2300 in this way, air outside the electronic control device 1 can move into the electronic control device 1 through the panel front openings 243.

The panel front opening diameter 243D may be set to approximately 0.3 mm to 2.5 mm. According to an embodiment, the panel front opening diameter 243D is set to approximately 0.5 mm to 2.0 mm. More specifically, the panel front opening diameter 243D is set to approximately 0.7 mm to 1.5 mm.

As the panel front opening diameter 243D is limited to the value, foreign substances OD such as liquid (e.g., water) cannot pass through the panel front opening 243. Accordingly, the water resistance of the electronic control device 1 can be improved.

By increasing the flow rate of air passing through the electronic control device 1 according to the present disclosure, the heat dissipation performance of the electronic control device 1 can be improved, and the water resistance of the electronic control device 1 can also be improved.

Although exemplary embodiments of the disclosure have been disclosed for illustrative purposes, those skilled in the art will appreciate that various modifications, additions and substitutions are possible, without departing from the scope and spirit of the disclosure as defined in the accompanying claims. Thus, the true technical scope of the disclosure should be defined by the following claims.

What is claimed is:

1. An electronic control device comprising:
a base part comprising a base plate;
a panel part comprising a panel body disposed on a front of the base part, a panel protrusion protruding outward from the panel body, and a panel ventilation unit comprising openings in the panel protrusion; and
a heat dissipation part comprising a heat dissipation body disposed on the base part to face the base plate.

2. The electronic control device as claimed in claim 1, further comprising a heat dissipation fan disposed inside of the panel body and configured to move air from outside of the panel part to inside of the panel part through the panel ventilation unit.

3. The electronic control device as claimed in claim 1, wherein the panel ventilation unit comprises panel lower openings that open toward a lower side of the panel body.

4. The electronic control device as claimed in claim 3, wherein the panel part comprises panel lower ribs disposed to connect the panel body and the panel protrusion and crossing the panel lower openings.

5. The electronic control device as claimed in claim 1, wherein the panel ventilation unit comprises panel side openings that open a side of the panel protrusion.

6. The electronic control device as claimed in claim 1, wherein the panel ventilation unit comprises panel front openings disposed in a direction in which the panel protrusion protrudes.

7. The electronic control device as claimed in claim 6, wherein the panel ventilation unit comprises panel front ribs that surround the panel front openings and protrude in a direction in which the panel protrusion protrudes.

8. The electronic control device as claimed in claim 1, wherein the base part comprises:
a side plate comprising a first side plate and a second side plate that extend from the base plate and are disposed on respective sides of the base plate;
a rear plate that extends from the base plate and is disposed to face the panel body; and
a front plate that extends from the base plate and is disposed between the rear plate and the panel body.

9. The electronic control device as claimed in claim 1, further comprising a control part disposed between the base part and the heat dissipation part and configured to generate heat.

10. The electronic control device as claimed in claim 1,
wherein the heat dissipation part comprises:
a heat dissipation body disposed to face the base plate; and
a heat dissipation fin unit disposed on an outside of the heat dissipation body and configured to dissipate heat,
further comprising a cover part disposed to cover the heat dissipation fin unit.
